(19) United States
(12) Patent Application Publication
(10) Pub. No.: US 2026/0362709 A1
(43) Pub. Date: Nov. 12, 2026

(54) TUNNELING-BASED SELECTORS INCORPORATING TWO-DIMENSIONAL (2D) MATERIALS

(71) Applicant: TetraMem Inc., Fremont, CA (US)

(72) Inventors: Minxian Zhang, Amherst, MA (US); Ning Ge, Danville, CA (US)

(73) Assignee: TetraMem Inc., Fremont, CA (US)

(21) Appl. No.: 19/204,371

(22) Filed: May 9, 2025

(51) Int. Cl. H10B 63/00

(52) U.S. Cl. CPC H10B 63/22

(57) ABSTRACT

In accordance with some embodiments of the present disclosure a tunneling-based selector is provided. The selector includes a multilayer barrier structure fabricated between a first electrode and a second electrode. The multilayer barrier structure includes a first layer of a first two-dimensional (2D) material; a second layer of a second 2D material; and a third layer of a third 2D material. The first layer of the first 2D material is fabricated between the second layer of the second 2D material and the third layer of the third 2D material. The first 2D material comprises gallium sulfide. The electron affinity of the first layer of the first 2D material is lower than the second electron affinity of the second layer of the second 2D material and the electron affinity of the third layer of the third 2D material.

### TECHNICAL FIELD

The implementations of the disclosure relate generally to selector devices and, more specifically, to tunneling-based selectors incorporating two-dimensional (2D) materials.

### BACKGROUND

High-density memory and computing devices, such as crossbar circuits including a circuit structure with interconnecting electrically conductive wires with resistive random-access memory devices at their intersections, require each memory cell to be paired with a selector device to enable reading and writing a selected memory cell. For example, a crossbar circuit may utilize a one-selector-one-resistor (1S1R) structure including a selector device serially connected to a memory cell to select particular memory cells for performing a read or write operation and to suppress undesirable leakage currents passing through unselected memristors.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, a selector is provided. The selector includes: a multilayer barrier structure fabricated between a first electrode and a second electrode, wherein the multilayer barrier structure includes: a first layer including a first two-dimensional (2D) material; a second layer including a second 2D material; and a third layer including a third 2D material. The first 2D material includes gallium sulfide (GaS). A first electron affinity of the first layer including the first 2D material is lower than a second electron affinity of the second layer including the second 2D material and a third electron affinity of the third layer including the third 2D material. The first layer including the first 2D material is fabricated between the second layer including the second 2D material and the third layer including the third 2D material.

In some embodiments, the first electrode includes graphene, a metal, or a nitride, and wherein the second electrode includes graphene, a metal, or a nitride.

In some embodiments, the second 2D material includes WS₂, wherein the third 2D material includes WS₂.

In some embodiments, the second 2D material includes MoS₂, wherein the third 2D material includes MoS₂.

In some embodiments, the second 2D material includes MoTe₂, herein the third 2D material includes MoTe₂.

In some embodiments, the second 2D material includes WSe₂, herein the third 2D material includes WSe₂.

In some embodiments, the multilayer barrier structure further includes a fourth layer of a fourth 2D material, wherein the second electron affinity of the second 2D material is lower than a fourth electron affinity of the fourth 2D material, and wherein the fourth layer of the fourth 2D material is fabricated between the second layer including the second 2D material and the first electrode.

In some embodiments, the multilayer barrier structure further includes a fifth layer of a fifth 2D material, wherein the third electron affinity of the third layer of the third 2D material is lower than a fifth electron affinity of the fifth layer of the fifth 2D material, and wherein the fifth layer of the fifth 2D material is fabricated between the third layer including the third 2D material and the second electrode.

In some embodiments, the second 2D material includes WSe₂, wherein the third 2D material includes WSe₂, and wherein the fourth 2D material and the fifth 2D material include at least one of MoTe₂, WS₂, or MoS₂.

In some embodiments, the second 2D material includes MoTe₂, wherein the third 2D material includes MoTe₂, and wherein the fourth 2D material and the fifth 2D material include at least one of WS₂ or MoS₂.

In some embodiments, the second 2D material includes WS₂, the third 2D material includes WS₂, and wherein the fourth 2D material and the fifth 2D material include MoS₂.

In some embodiments, the multilayer barrier structure includes 2n+1 layers of 2D materials, wherein n is a positive integer.

In some embodiments, the multilayer barrier structure forms a staircase tunnel barrier approximating a triangular tunnel barrier.

According to one or more aspects of the present disclosure, an apparatus is provided. The apparatus includes: a selector including: a multilayer barrier structure fabricated between a first electrode and a second electrode; and a memory device serially connected to the selector. The multilayer barrier structure includes: a first layer including a first two-dimensional (2D) material; a second layer including a second 2D material; and a third layer including a third 2D material. The first 2D material includes gallium sulfide (GaS). A first electron affinity of the first layer including the first 2D material is lower than a second electron affinity of the second layer including the second 2D material and a third electron affinity of the third layer including the third 2D material.

In some embodiments, the memory device includes at least one of a memristor, resistive random-access memory (RRAM), phase-change memory (PCM), magneto-resistive random-access memory (MRAM), floating gates, spintronic devices, dynamic random-access memory (DRAM), ferroelectric random-access memory (FeRAM), or static random-access memory (SRAM).

In some embodiments, the second 2D material includes at least one of MoS₂, WS₂, MoTe₂, or WSe₂, and wherein the third 2D material includes at least one of MoS₂, WS₂, MoTe₂, or WSe₂.

In some embodiments, the multilayer barrier structure further includes a fourth layer of a fourth 2D material, wherein the second electron affinity of the second 2D material is lower than a fourth electron affinity of the fourth 2D material, wherein the fourth layer of the fourth 2D material is fabricated between the second layer including the second 2D material and the first electrode, and wherein the multilayer barrier structure further includes a fifth layer of a fifth 2D material, wherein the third electron affinity of the third layer of the third 2D material is lower than a fifth electron affinity of the fifth layer of the fifth 2D material, and wherein the fifth layer of the fifth 2D material is fabricated between the third layer including the third 2D material and the second electrode.

In some embodiments, the second 2D material includes WSe₂, wherein the third 2D material includes WSe₂, and wherein the fourth 2D material and the fifth 2D material include at least one of MoTe₂, WS₂, or MoS₂.

In some embodiments, the second 2D material includes MoTe₂, wherein the third 2D material includes MoTe₂, and wherein the fourth 2D material and the fifth 2D material include at least one of WS₂ or MoS₂.

In some embodiments, the second 2D material includes WS₂, wherein the third 2D material includes WS₂, and wherein the fourth 2D material and the fifth 2D material include MoS₂.

In some embodiments, the selector has a staircase tunnel barrier approximating a triangular tunnel barrier.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIG. 1 is a schematic diagram illustrating a cross-sectional view of an example selector in accordance with some embodiments of the present disclosure.

FIGS. 2A, 2B, and 2C are schematic diagrams illustrating cross-sectional views of example selectors in accordance with some embodiments of the present disclosure.

FIG. 3A is a schematic diagram illustrating an example of a crossbar circuit in accordance with some embodiments of the present disclosure.

FIG. 3B is a schematic diagram illustrating an example cross-point device in accordance with some embodiments of the present disclosure.

FIG. 4 is a diagram illustrating bandgaps and electron affinities of example 2D materials in accordance with some embodiments of the present disclosure.

FIG. 5 is a diagram illustrating current-voltage (I-V) characteristics of a selector in accordance with some embodiments of the present disclosure.

FIG. 6 is a diagram illustrating nonlinearity of a selector in accordance with some embodiments of the present disclosure.

FIGS. 7A and 7B are diagrams illustrating example energy barriers in accordance with some embodiments of the present disclosure.

FIGS. 8A and 8B are schematic diagrams illustrating cross-sectional views of example 1S1R structures in accordance with some embodiments of the present disclosure.

FIGS. 9 and 10 are flow diagrams illustrating example methods for fabricating a selector and an apparatus including a 1S1R structure in accordance with some embodiments of the present disclosure.

### DETAILED DESCRIPTION

Aspects of the disclosure provide tunneling-based selectors incorporating two-dimensional (2D) materials and mechanisms for fabricating the selectors. As used herein, two-dimensional (2D) materials may refer to crystalline materials consisting of single or a few atomic layers, thereby confining electron movement to a two-dimensional plane and exhibiting properties different from their three-dimensional bulk forms. Examples of 2D materials may include van der Waals (vdW) materials, 2D materials fabricated using remove epitaxy techniques, MXenes, etc. A vdW material may include van der Waals heterostructures including strongly bonded 2D layers (one-atom-thick sheets) that are stacked together via van der Waals interactions and can be exfoliated into thin 2D free-standing layers. Examples of vdW materials include SnS₂ (tin sulfide), ZrS₂ (zirconium sulfide), SnSe₂ (stannic selenide), HfS₂ (hafnium disulfide), MoS₂ (molybdenum disulfide), MoSe₂ (molybdenum diselenide), MoTe₂ (molybdenum ditelluride), WS₂ (tungsten disulfide), WSe₂ (tungsten diselenide), graphene (Gr), h-BN (Hexagonal boron nitride), etc.

Remote epitaxy is a crystal growth technique that leverages the unique properties of two-dimensional (2D) materials, such as van der Waals (vdW) materials, to fabricate high-quality, single-crystal thin films. Unlike conventional epitaxy techniques, where the grown layer is in direct contact with and directly copies the crystal structure of the substrate, remote epitaxy introduces a 2D material (e.g., graphene or hexagonal boron nitride) as a semi-transparent interlayer. This interlayer allows the crystallographic information from the substrate to ‘remotely’ propagate through it, templating the crystalline orientation of the overlying thin film grown on the 2D material, and enables the exfoliation of the film from the host substrate for a free-standing 2D film. Examples of remote epitaxy 2-D thin-films include oxide (VO₂), nitride (GaN), sulfide (WS₂), etc.

MXenes may refer to a class of two-dimensional transition-metal carbides and nitrides. The “M” in MXene stands for an early transition metal, such as Titanium (Ti), Vanadium (V), Chromium (Cr), or Niobium (Nb), while “X” represents a non-metal, typically carbon (C) to form a carbide (MX is carbide) or nitrogen (N) to form a nitride (MX is nitride). MXenes are synthesized from precursor compounds known as MAX phases, which are layered ternary carbides or nitrides with the general formula Mₙ₊₁AXₙ. In these MAX phases, “A” represents an element from group 13, 14, or 16 of the periodic table, commonly Aluminum (Al), Gallium (Ga), Silicon (Si), or Sulfur(S). The MAX phases possess a hexagonal crystal structure where layers of Mₙ₊₁Xₙ are interleaved with layers of the pure “A” element. Selective etching of the “A” element from the MAX phase may yield free-standing Mₙ₊₁Xₙ 2D films. It's generally observed that MXenes derived from MAX phases with higher values of ‘n’ (e.g., M₃X₂, M₄X₃) are more stable, although they are also inherently thicker.

Memory and computing devices, such as memristor-based crossbar arrays, may require selector devices to select particular memory and/or computing elements and suppress undesirable sneaking currents passing through the partially selected or unselected memory and/or computing elements. While transistors are widely used as selectors in crossbar arrays, third-terminal transistor-based selectors are not ideal for crossbar arrays as their large footprints may limit array density and increase costs. As such, it might be desirable to use two-terminal selectors that may be scaled laterally and stacked vertically together with a memory cell (e.g., a memristor) to implement crossbar arrays. However, conventional two-terminal selectors do not possess certain desirable characteristics required for implementing crossbar arrays and similar computing and/or memory applications, such as high nonlinearity, high endurance, a sufficient current density, and small variance from device to device.

The present disclosure provides tunneling-based selectors with a multilayer staircase tunneling barrier to approximate a desirable triangular tunnel barrier. The selectors can be used in memory applications and computing applications, such as in-memory computing applications, non-volatile solid-state memory, multilevel memory, image processing applications, neural networks, etc.

According to one or more aspects of the present disclosure, a selector may include a first electrode, a second electrode, and a multilayer barrier structure fabricated between the first electrode and the second electrode. The first electrode and the second electrode may include graphene or any other material with suitable electrical conductivity.

The multilayer barrier may include multiple layers of 2D materials and may form a staircase tunneling barrier to approximate a triangular tunnel barrier. The multilayer barrier structure may include a central layer of a first 2D material sandwiched between layers of 2D materials having higher electron affinities than the first 2D material. The multilayer barrier structure may include any suitable number of layers of 2D materials (e.g., 2n+1 layers, where n is a positive integer), where the electron affinity of an inner layer in the multilayer barrier structure is lower than that of its adjacent outer layer, where the inner layer is closer to the central layer than the outer layer. As an example, the multilayer barrier structure may include a layer of gallium sulfide (GaS) sandwiched between two layers of MoS₂. As another example, the multilayer barrier structure may include a layer of GaS sandwiched between two layers of WS₂. As a further example, the multilayer barrier structure may include a layer of GaS sandwiched between a first layer of WSe₂ and a second layer of MoTe₂. In some embodiments, the first electrode and the second electrode both include graphene.

The multilayer barrier structure may approximate a triangular tunnel barrier with a height peak in the middle of the energy barrier. An electric field may reduce the peak barrier height and the barrier width of the triangular tunnel barrier compared to the case of a rectangular or uniform tunnel barrier where the barrier width may be reduced, but the barrier height may not be reduced. The barrier height of a rectangular tunnel barrier may not be reduced with an external voltage as possessed by many existing tunneling-based selector devices. Therefore, the tunneling current through the triangular tunnel barrier may change abruptly responsive to an electric field applied to the selector, resulting in high nonlinearity of the selector. The nonlinearity of the selector may be measured by a nonlinearity factor representative of a ratio of the current passing through the selector at a threshold voltage for switching the selector to a conductive state and the current passing through the selector at half of the threshold voltage. The nonlinearity factor of the selector may exceed 10⁷ in some embodiments.

The selectors described herein also exhibit high endurance (e.g., remaining functional as designed after at least 10⁸ applications of read or write operations), excellent uniformity, and good thermal stability. The selectors may provide a sufficient drive current density (e.g., a current density greater than 10⁶ μA/cm2) for implementing many memory applications or computing applications. The selectors described herein may thus enable high-density memory and/or computing applications that require high device uniformity and selectivity.

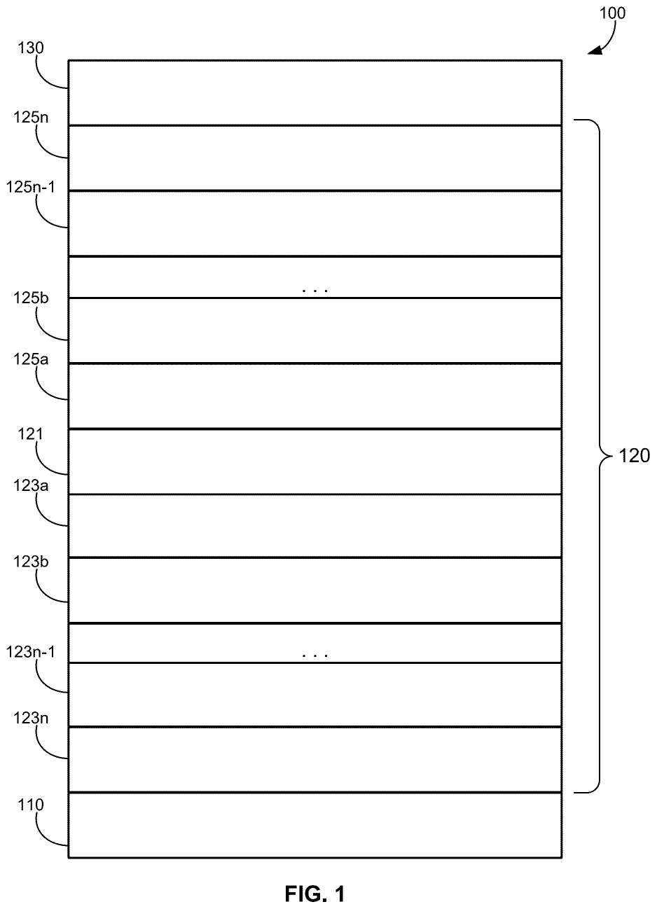

FIG. 1 is a schematic diagram illustrating a cross-sectional view of an example selector 100 in accordance with some embodiments of the present disclosure. The selector 100 may be a two-terminal device having exactly two terminals and may have a multilayer tunnel barrier structure to approximate a triangular tunnel barrier.

As shown, the selector 100 may include a first electrode 110, a multilayer barrier structure 120, and a second electrode 130. The first electrode 110 and the second electrode 130 may include a material of suitable electrical conductivity, such as graphene.

The multilayer barrier structure 120 may be fabricated on the first electrode 110. The multilayer barrier structure 120 may include multiple layers of 2D materials that form a staircase tunnel barrier that may approximate a triangular tunnel barrier. As illustrated in FIG. 1, the multilayer barrier structure 120 may include 2n+1 layers, where “1” represents a layer of a 2D material at the center of the tunnel barrier (the “central layer 121”) and n is a positive integer (e.g., 1, 2, 3, . . . ) representative of the number of the layers of 2D materials between the central layer 121 and the first electrode 110 or the number of the layers between the central layer 121 and the second electrode 130.

For example, the multilayer barrier structure 120 may include a central layer 121 fabricated between the first electrode 110 and the second electrode 130. The central layer 121 may include a first 2D material. The multilayer barrier structure 120 may further include one or more layers 123 fabricated between the first electrode 110 and the central layer 121 and one or more layers 125 fabricated between the central layer 121 and the second electrode 130. As such, the central layer 121 is sandwiched between n layer(s) 123 and n layer(s) 125. Each layer 123 and/or 125 may include a 2D material that is different from the first 2D material.

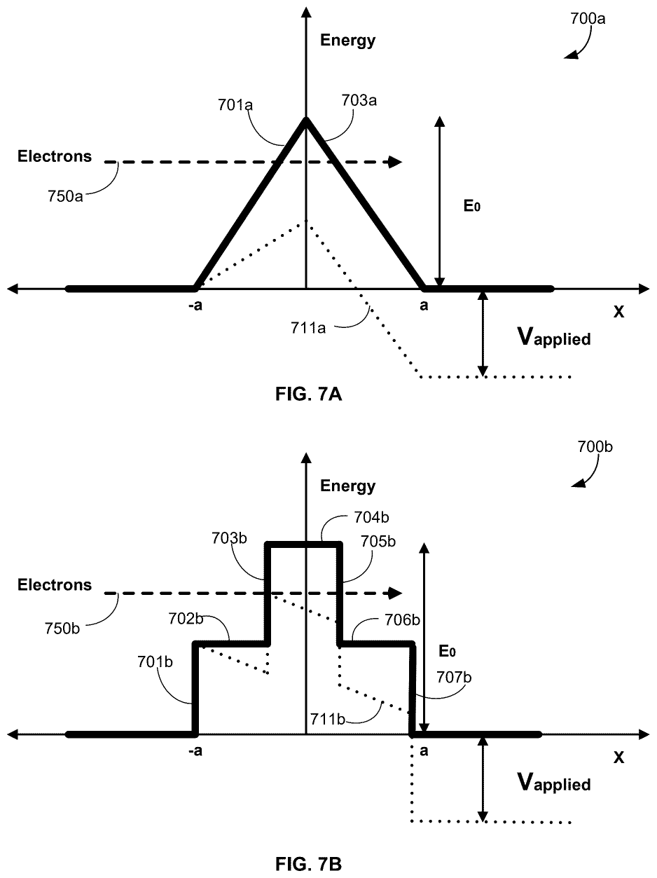

The selector 100 and the multiplayer barrier structure 120 may have a staircase energy barrier that may approximate a desirable triangular energy barrier (e.g., a staircase energy barrier 700b as described in connection with FIG. 7B). The multilayer barrier structure 120 may include any suitable number of layers of 2D materials to form the staircase energy barrier. In some embodiments, the multilayer barrier structure 120 may include five layers of 2D materials. A selector with relatively more layers of 2D materials may form a staircase tunnel barrier with finer steps and may better approximate the triangular tunnel barrier than a selector with relatively fewer layers of 2D materials.

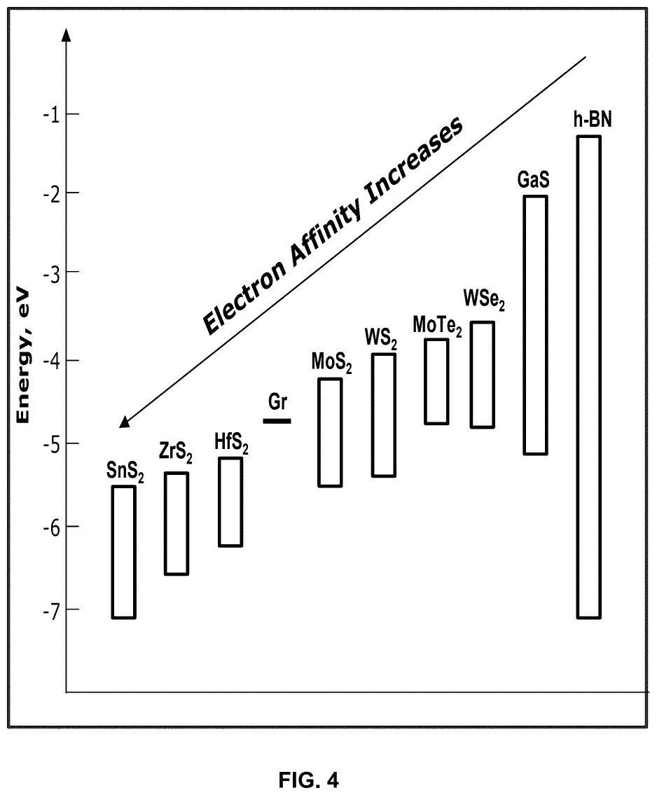

The 2D materials in various layers of the multilayer barrier structure 120 may have varying electron affinities. The electron affinity of a material may refer to the amount of energy liberated when an electron is added to a neutral atom of the material to form a negatively charged ion. As will be discussed in greater detail in connection with FIG. 4, different 2D materials may have varying electron affinities. For example, disulfide (SnS₂), zirconium disulfide (ZrS₂), hafnium disulfide (HfS₂), graphene (Gr), molybdenum disulfide (MoS₂), tungsten disulfide (WS₂), molybdenum ditelluride (MoTe₂), tungsten diselenide (WSe₂), gallium sulfide (GaS), and hexagonal Boron Nitride (h-BN) have decreasing electron affinities. The 2D material in the central layer may have the lowest electron affinity among the 2D materials in the multilayer barrier structure 120. The electron affinities of the 2D materials in the n layers positioned between the central layer 121 and the first electrode 110 may possess increasing electron affinities from the layer closest to the central layer 121 (i.e., the layer 123a) towards the layer closest to the first electrode 110 (i.e., the layer 123n). The electron affinities of the 2D materials in the n layers positioned between the central layer 121 and the second electrode 130 may possess increasing electron affinities from the layer closest to the central layer 121 (i.e., the layer 125a) towards the layer closest to the second electrode 130 (i.e., the layer 125n). The electron affinities of layers 123a-n and the electrode affinities of layer 125a-n may increase symmetrically or asymmetrically. For example, the electron affinities of the layer 123a and the layer 125a may or may not be the same. The electron affinities of the layer 123n and the layer 125n may or may not be the same.

More particularly, for example, the electron affinity of the central layer 121 is lower than the electron affinity of each layer 123 and/or 125. The electron affinity of an inner layer in the multilayer barrier structure 120 is lower than that of its adjacent outer layer, where the inner layer is closer to the central layer 121 than the outer layer. For example, the electron affinity of the layer 123a is lower than that of the layer 123b. The electron affinity of the layer 123n−1 is lower than that of the layer 123n. As another example, the electron affinity of the layer 125a is lower than that of the layer 125b. The electron affinity of the layer 125n−1 is lower than that of the layer 125n.

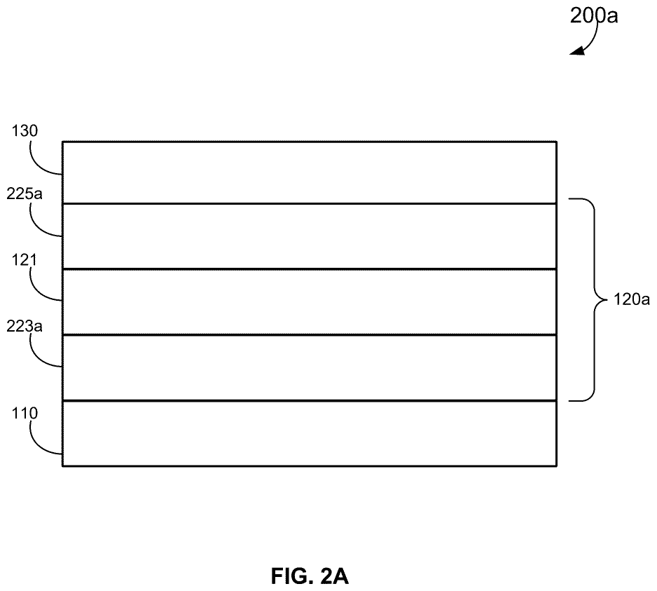

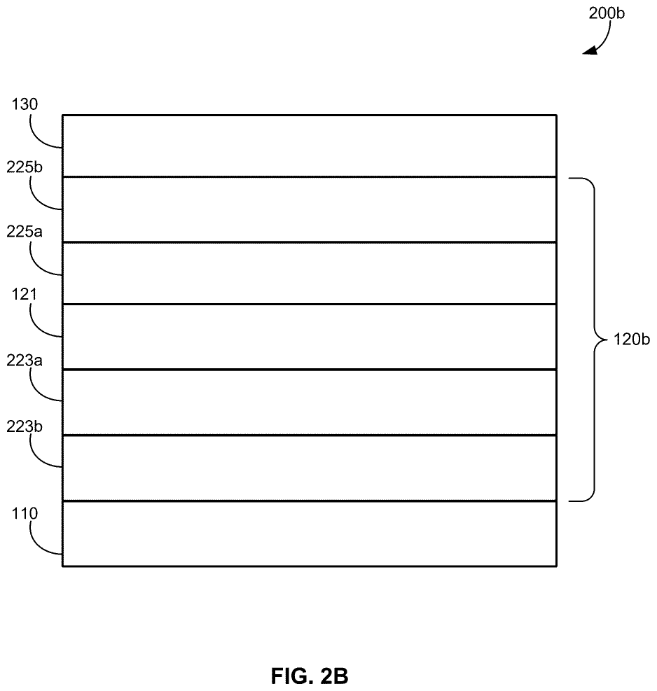

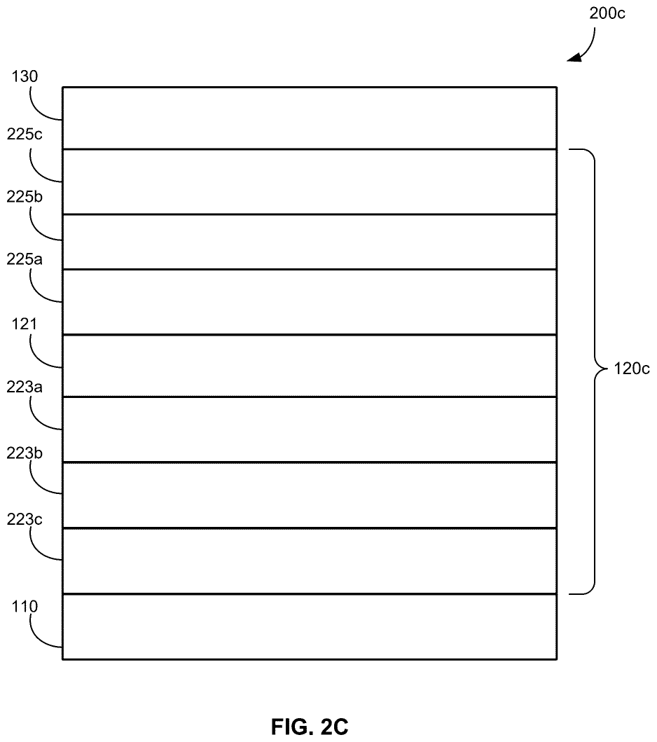

The multilayer barrier structure 120 may include one or more of multilayer barrier structures 120a, 120b, and 120c as described in connection with FIGS. 2A-2C below.

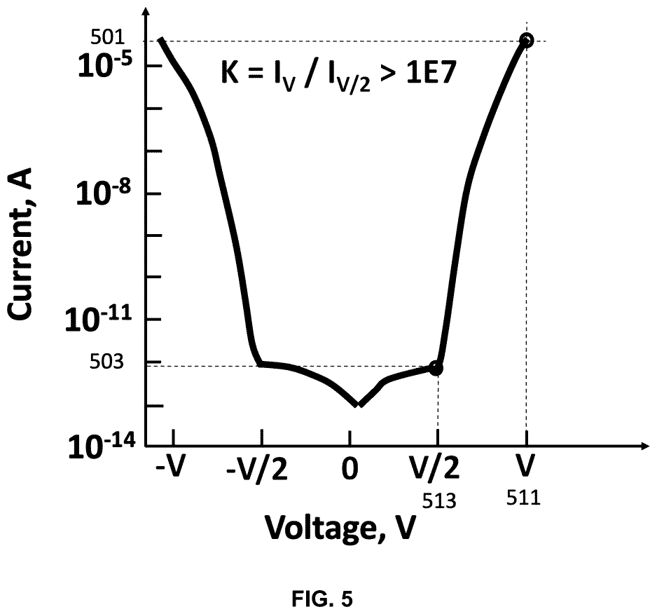

As will be described in greater detail in connection with FIG. 5, the selector 100 may be in a high-resistance state (an OFF state) when the voltages applied to the selector 100 is below one-half of a threshold voltage V (+V/2 or −V/2). When the voltage applied to the selector 100 reaches or exceeds the threshold voltage V, the selector 100 is conductive and in an ON state.

FIGS. 2A-2C are schematic diagrams illustrating cross-sectional views of examples 200a, 200b, and 200c of a selector in accordance with some embodiments of the present disclosure.

As shown in FIG. 2A, the selector 200a may include the first electrode 110 and the second electrode 130 as described in connection with FIG. 1. In some embodiments, both the first electrode 110 and the second electrode 130 may include Gr. The selector 200a may further include a multilayer barrier structure 120a including a plurality of layers of 2D materials, as an example of 2n+1 multilayer barrier structure with n=1.

The multilayer barrier structure 120a may include a central layer 121 of a first 2D material (also referred to as the “first layer of the first 2D material”), a second layer 223a of a second 2D material, and a third layer 225a of a third 2D material. The electron affinity of the central layer 121 and/or the first 2D material (also referred to as the “first electron affinity”) is lower than the electron affinity of the second layer 223a and/or the second 2D material (also referred to as the “second electron affinity”) and the electron affinity of the third layer 225a and/or the third 2D material (also referred to as the “third electron affinity”). As an example, the first 2D material may be GaS. The second 2D material and the third 2D material may be and/or include any suitable 2D material having an electron affinity greater than the first electron affinity, such as SnS₂, HfS₂, ZrS₂, Gr, MoS₂, WS₂, WSe₂, etc. In one implementation, the central layer 121, the second layer 223a, and the third layer 225a may be a layer of GaS, a layer of WSe₂, and a layer of WSe₂, respectively. In another implementation, the central layer 121, the second layer 223a, and the third layer 225a may be a layer of GaS, a layer of WS₂, and a layer of WS₂, respectively. In another implementation, the central layer 121, the second layer 223a, and the third layer 225a may be a layer of GaS, a layer of MoS₂, and a layer of MoS₂, respectively. In a further implementation, the central layer 121, the second layer 223a, and the third layer 225a may be a layer of GaS, a layer of MoTe₂, and a layer of MoTe₂, respectively.

As shown in FIG. 2B, the selector 200b may include the first electrode 110 and the second electrode 130 as described in connection with FIG. 1. The selector 200b may further include a multilayer barrier structure 120b including a plurality of layers of 2D materials. The multilayer barrier structure 120n is an example of 2n+1 multilayer barrier structure with n=2.

The multilayer barrier structure 120b may include the first layer 121 including the first 2D material, the second layer 223a of the second 2D material, and the third layer 225a of the third 2D material. The multilayer barrier structure 120b may further include a fourth layer 223b of a fourth 2D material fabricated between the second layer 223a of the second 2D material and the first electrode 110. The multilayer barrier structure 120b may further include a fifth layer 225b of a fifth 2D material fabricated between the third layer 225a of the third 2D material and the second electrode 130. The electron affinity of the second 2D material (the second electron affinity) is lower than the electron affinity of the fourth 2D material (also referred to as the “fourth electron affinity”). The electron affinity of the third 2D material (the third electron affinity) is lower than the electron affinity of the fifth 2D material (also referred to as the “fifth electron affinity”). As an example, the first 2D material may be GaS. The second 2D material and the third material may be WSe₂. The fourth 2D material and the fifth 2D material may be at least one of MoTe₂, WS₂, or MoS₂. As another example, the first 2D material may be GaS. The second 2D material and the third 2D material may be MoTe₂. The fourth 2D material and the fifth 2D material may be WS₂ and/or MoS₂. As a further example, the first 2D material may be GaS. The second 2D material and the third 2D material may be WS₂. The fourth 2D material and the fifth 2D material may be MoS₂.

Referring to FIG. 2C, the selector 200c may include the first electrode 110 and the second electrode 130 as described in connection with FIG. 1. The selector 200c may further include a multilayer barrier structure 120c including a plurality of layers of 2D materials. The multilayer structure 120c is an example of 2n+1 multilayer barrier structure with n=3. The multilayer barrier structure 120c may include the layers 121, 223a, 223b, 225a, and 225b as described in connection with FIG. 2B above. The multilayer barrier structure 120c may further include a sixth layer 223c of a sixth 2D material and a seventh layer 225c of a seventh 2D material. The sixth layer 223c is fabricated between the fourth layer 223b and the first electrode 110. The seventh layer 225c is fabricated between the fifth layer 225b and the second electrode 130. The electron affinity of the fourth 2D material (the fourth electron affinity) is lower than the electron affinity of the sixth 2D material (also referred to as the “sixth electron affinity”). The electron affinity of the fifth 2D material (the fifth electron affinity) is lower than the electron affinity of the seventh 2D material (also referred to as the “seventh electron affinity”). For example, the first 2D material may be GaS. The second 2D material and the third 2D material may be WSe₂. The fourth 2D material and the fifth 2D material may be MoTe₂. The sixth 2D material and the seventh 2D material may be WS₂. As another example, the first 2D material may be GaS. The second 2D material and the third 2D material may be WSe₂. The fourth 2D material and the fifth 2D material may be WS₂. The sixth 2D material and the seventh 2D material may be MoS₂. As a further example, the first 2D material may be GaS. The second 2D material and the third 2D material may be WSe₂. The fourth 2D material and the fifth 2D material may be MoTe₂. The sixth 2D material and the seventh 2D material may be MoS₂. As yet another example, the first 2D material may be GaS. The second 2D material and the third 2D material may be MoTe₂. The fourth 2D material and the fifth 2D material may be WS₂. The sixth 2D material and the seventh 2D material may be MoS₂.

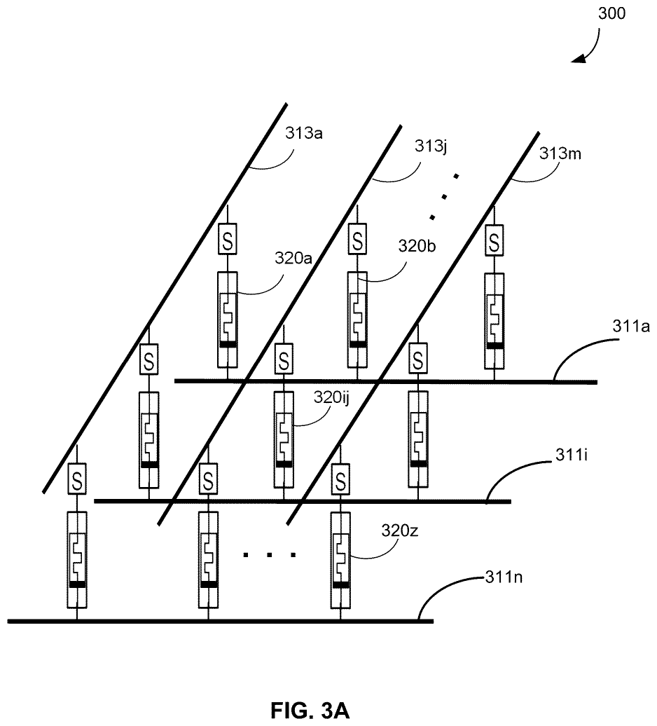

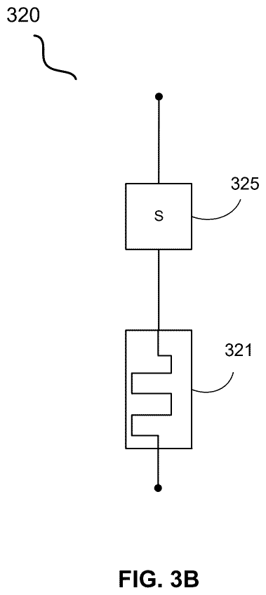

FIG. 3A is a schematic diagram illustrating an example 300 of a crossbar circuit in accordance with some embodiments of the present disclosure. As shown, crossbar circuit 300 may include a plurality of interconnecting electrically conductive wires, such as one or more bit lines 311a, . . . , 311i, . . . , 311n, and word lines 313a, . . . , 313j, . . . , 313m for an n-row by m-column crossbar array. The crossbar circuit 300 may further include cross-point devices 320a, 320b, . . . , 320z, etc. Each of the cross-point devices may be connected to a bit line and a word line. For example, the cross-point device 320ij may connect the bit line 311i and the word line 313j.

In some embodiments, crossbar circuit 300 may further include digital to analog converters (DAC, not shown), analog to digital converters (ADC, not shown), switches (not shown), and/or any other suitable circuit components for implementing a crossbar-based apparatus. The number of the word lines 313a-m and the number of the bit lines 311a-n may or may not be the same.

Bit lines 311 may include a first bit line 311a, a second bit line 311i, . . . , and a n-th bit line 311n. Each of bit lines 311a, . . . , 311n may be and/or include any suitable electrically conductive material. In some embodiments, each bit line 311a-n may be a metal wire.

Word lines 313 may include a first word line 313a, a second word line 313j, . . . , and a m-th word line 313m. Each of word lines 313a-m may be and/or include any suitable electrically conductive material. In some embodiments, each word line 313a-m may be a metal wire.

Each cross-point device 320 may be and/or include a selector and one or more memory devices, such as a memristor, resistive random-access memory (RRAM), magneto-resistive random-access memory (MRAM), phase-change memory (PCM), floating gates, spintronic devices, dynamic random-access memory (DRAM), ferroelectric random-access memory (FeRAM), static random-access memory (SRAM), etc. Each of the cross-point device 320 may include one or more components as described in connection with FIG. 3B below. In some embodiments, one or more of the cross-point devices 320 may include a selector serially connected to a plurality of memristor devices (also referred to as a 1SnR structure).

One or more of the cross-point devices 320 may be selected to perform an operation (e.g., a read operation, a write operation, etc.). For example, to select the cross-point device 320ij, a suitable programming voltage equivalent to the selector threshold voltage V may be applied to the cross-point device 320ij. More particularly, for example, a voltage of +V/2 and a voltage of −V/2 may be applied to the selected word line 313j and the selected bit line 311i, respectively. Therefore, the voltage across the cross-point device 320ij is a full voltage V. The cross-point device is thus turned into an ON state. The other cross-point devices that are connected to the word line 313j and the other cross-point devices that are connected to the bit line 311i are regarded as being half-selected devices, as each of these devices is subject to either the voltage of +V/2 or the voltage of −V/2. The half-selected devices may remain in an OFF state. The cross-point devices that are neither connected to the word line 313j nor the bit line 313i are unselected devices and may also remain in an OFF state. The ON/OFF states of the cross-point device are consistent with the ON/OFF states of the selector. That is, the cross-point device and the selector are in the ON state when the voltage applied to the selector is higher than the threshold voltage V and the cross-point device and the selector are Off when the voltage applied to the selector is lower than half of the threshold voltage +V/2 or −V/2. In a 1S1R configuration in which one selector device is serially connected to one memory device, the selector's resistance in the OFF state is much higher than that of the memory device. Therefore, according to the voltage division rule, the selector produces a voltage drop that is significantly greater than the voltage drop produced by the memory device. The voltage applied to the cross-point device will drop across the selector to turn the selector to the ON state. Once the selector is turned ON (e.g., being conductive), the voltage applied to the cross-point device will drop mainly across the memory device for operations of the memory device, according to the voltage division rule. When the selector is turned ON, the memory device connected to the selector is selected. As will be discussed in greater detail below, the memory device may be electrically switched between a high-resistance state (HRS) and a low-resistance state (LRS) by applying suitable programming signals to the memory device. As such, the memory device may have resistance states or memory states that are independent of the ON/OFF states of the cross-point devices.

Crossbar circuit 300 may perform parallel weighted voltage multiplication and current summation. For example, an input voltage signal may be applied to one or more rows of crossbar circuit 300 (e.g., one or more selected rows). The input signal may flow through the cross-point devices of the rows of the crossbar circuit 300. The conductance of the cross-point memory device may be tuned to a specific value (also referred to as a “weight”). By Ohm's law, the input voltage multiplied by the cross-point memory conductance generates a current from the cross-point device. By Kirchhoff's law, the summation of the current passing the devices on each column generates the current as the output signal, which may be read from the columns (e.g., outputs of the ADCs). According to Ohm's law and Kirchhoff's current law, the input-output relationship of the crossbar array can be represented as I=VG, wherein I represents the output signal matrix as current; V represents the input signal matrix as voltage; and G represents the conductance matrix of the cross-point devices. As such, the input signal is weighted at each of the cross-point devices by its conductance according to Ohm's law. The weighted current is output via each word line and may be accumulated according to Kirchhoff's current law. This may enable in-memory computing (IMC) via parallel multiplications and summations performed in the crossbar arrays.

FIG. 3B is a schematic diagram illustrating an example 320 of a cross-point device in accordance with some embodiments of the present disclosure. As illustrated, cross-point device 320 may include a memory device 321 and a selector 325 that is serially connected to the memory device 321.

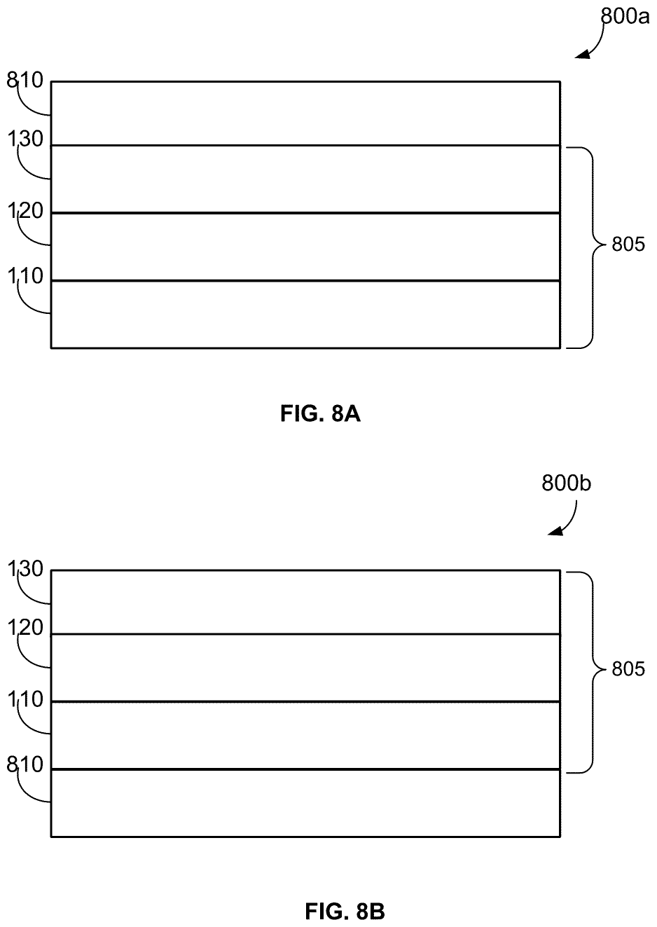

The memory device 321 may include a switching oxide layer fabricated between a top electrode and a bottom electrode. The switching oxide layer may include one or more transition metal oxides, such as at least one of HfOₓ or TaOₓ, wherein x may be used to indicate the oxide being oxygen deficient compared to its full (or terminal) oxide and the value of x may be varied from the oxygen to metal atomic ratio in the stoichiometry of its full oxide, such as x≤2.0 for HfOx (where HfO₂ being the full oxide), and x≤2.5 for TaOx (where Ta₂O₅ being the full oxide). In some embodiments, as will be described in greater detail in connection with FIGS. 8A and 8B, the memory device 321 and the selector 325 may be stacked vertically so that the memory device 321 and the selector 325 may share the same electrode as the top electrode of one device and the bottom electrode of the other device.

The resistance of the memory device 321 may be electrically switched between a high-resistance state (HRS) and a low-resistance state (LRS) by applying suitable programming signals to the RRAM device. For example, the RRAM device may be in an initial state or virgin state and may have an initial high resistance before it is subject to an electrical simulation (e.g., a voltage or current signal applied to the RRAM device). The memory device 321 may be tuned to a lower resistance state from the virgin state via a forming process or from an HRS to an LRS via a forming process. The forming process may refer to programming a device starting from the virgin state. The setting process may refer to programming a device starting from the HRS.

The selector 325 may be and/or include the selectors 100, 200a, 200b, and/or 200c as described in connection with FIGS. 1-2C above. The selector 325 is a two-terminal device that may act as a bipolar switch to control currents across the memory device 321. The current that passes through the selector varies non-linearly with the voltage applied to the selector. The selector 325 may be in a high-resistance state when the voltage applied to the selector 325 is below one-half of the threshold voltage (+V/2 or −V/2). When the voltage applied to the selector 325 reaches or exceeds the threshold voltage V, the selector 325 is conductive, and the memory device 321 connected to the selector is selected to operate. A suitable programming voltage (a voltage equal to greater than the threshold voltage) may be applied to the cross-point device 320 to program the memory device 321 to a desirable conductance.

FIG. 4 is a diagram illustrating estimated bandgaps and electron affinities of example 2D materials in accordance with some embodiments of the present disclosure. As shown, each 2D material is associated with a particular energy band Eg (where the rectangular bars represent the band gaps of the selected 2D materials corresponding to the difference between the lowest energy of the conduction band (E_{C}) and the highest energy of the valence band (E_{V})). Different 2D materials may have varying electron affinities as shown in FIG. 4. For example, as shown in FIG. 4, SnS₂, ZrS₂, HfS₂, Gr, MoS₂, WS₂, MoTe₂, WSe₂, GaS, and h-BN have decreasing electron affinities. Among the 2D materials illustrated in FIG. 4, h-BN has the lowest electron affinity and the largest band gap, making it an ideal candidate as the first 2D layer at the center of the multi-layer structure. The large bandgap of an h-BN-centred stack suppresses Off-state leakage current at biases below roughly half of the threshold voltage. The large bandgap of an h-BN-centred stack suppresses Off-state leakage current at biases below roughly half of the threshold voltage, yielding very high non-linearity and, consequently, excellent selector performance. However, the large band gap of h-BN may also require a large threshold voltage or operation voltage to switch the selectors. To lower that operating voltage while preserving acceptable non-linearity, gallium sulfide (GaS) can replace h-BN as the middle layer. GaS-based tunnel selectors are expected to achieve substantially reduced threshold voltages with only a modest drop in non-linearity, making them well suited for low-power applications.

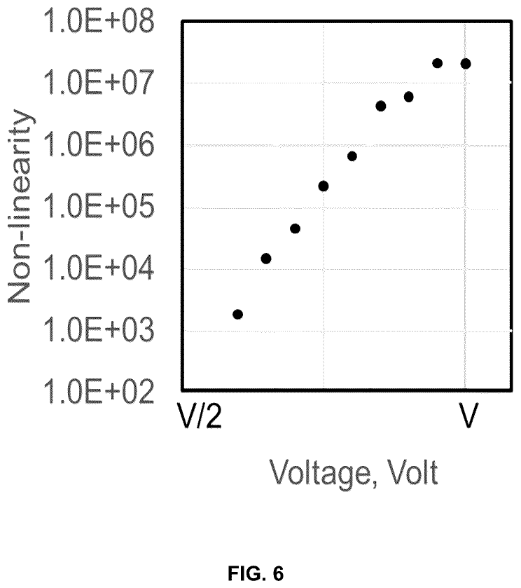

FIG. 5 is a diagram illustrating current-voltage (I-V) characteristics of a selector in accordance with some embodiments of the present disclosure. As shown, the selector exhibits current-voltage nonlinearity. That is, the current that passes through the selector varies non-linearly with the voltage applied to the selector. The nonlinearity of the selector may be measured by a nonlinearity factor K corresponding to a ratio of the current at a full voltage V (e.g., a current 501 corresponding to a voltage 511 as shown in FIG. 5) to the current at a half of the full-voltage V/2 (e.g., a current 503 corresponding to a voltage 513 as shown in FIG. 5). The full voltage V may be a threshold voltage that may switch the selector to a conductive state. That is, when the voltage applied to the selector reaches or exceeded the full voltage V, the selector is conductive, and a memory or computing cell controlled by the selector is selected. As shown in FIG. 6, the value of K may be about or greater than 10⁷. As such, the selectors disclosed herein exhibit high nonlinearity.

FIG. 6 is a diagram illustrating nonlinearity of a selector in accordance with some embodiments of the present disclosure. As shown, the nonlinearity factor K of the selector may be greater than 10⁷. The value of K may also be greater than 10², 10⁵, etc. for various applications. Accordingly, the selector possesses a desirable high nonlinearity.

FIG. 7A is a band diagram of an example tunnel barrier 700a of a selector in accordance with some embodiments of the present disclosure. The energy barrier 700a is in a triangular shape defined by symmetric lines 701a and 703a with a barrier height of E₀ at the center of the barrier. The tunnel barrier 700a is also referred to as a triangular tunnel barrier. The total width of the barrier is 2a (from −a to +a on X-axis). Without an external voltage V_{applied}, electrons with energies lower than E₀ (represented by the arrow 750a) need to tunnel through the energy barrier. As such, the current passing through the selector is low and the selector is in an OFF state. With an external voltage V_{applied} being applied across the selector, the energy barrier is lowered as shown by the dotted lines 711a. The electrons represented by the arrow 750a can move freely across the barrier. As such, the current passing through the selector is high, and the selector is in an ON state (a conductive state).

FIG. 7B is a band diagram of an example energy barrier 700b of a selector in accordance with some embodiments of the present disclosure. The energy barrier 700b is also referred to as a staircase energy barrier and can approximate the triangular tunnel barrier 700a of FIG. 7A. As shown, the energy barrier 700b is in a staircase shape defined by lines 701b, 702b, 703b, 704b, 705b, 706b, and 707b with a barrier height of E₀ at the center of the barrier. The total width of the barrier is 2a (from −a to +a on X-axis). This could be an example of 2n+1 layers with n=1 as shown in FIG. 2A with a center layer 121 sandwiched between a layer 223a and a layer 225a. While the energy barrier 700b is symmetric with respect to the Y-axis representative energy, this is merely illustrative. In some embodiments, the energy barrier 700 is not symmetric with respect to the Y-axis.

Without an external voltage V_{applied}, electrons with energies lower than E₀ (represented by the arrow 750b) need to tunnel through the energy barrier. As such, the current passing through the selector is low and the selector is in an OFF state. With an external voltage V_{applied} being applied across the selector, the energy barrier is lowered as shown in the dotted lines 711b. The electrons represented by the arrow 750b can move freely across the barrier. As such, the current passing through the selector is high and the selector is in an ON state (a conductive state). A selector with more layers of 2D materials may have a staircase energy barrier with finer steps and may thus better approximate the triangular tunnel barrier 700a than a selector with relatively fewer layers of 2D materials.

FIGS. 8A and 8B are schematic diagrams illustrating cross-sectional views of example 1S1R structures in accordance with some embodiments of the present disclosure.

As shown in FIG. 8A, 1S1R structure 800a may include a first electrode 110, a multilayer barrier structure 120 fabricated on the first electrode 110, a second electrode 130 fabricated on the multilayer barrier structure 120 to complete a selector 805. A memory device 810 may be fabricated on the second electrode 130 of the selector 805. The memory device 810 may have its own device stack including a bottom electrode, switching oxides, and a top electrode, etc. In some embodiments, the memory device 810 may share one or more electrodes with the selector 805 (e.g., by using the second electrode 130 as its bottom electrode). The first electrode 110, the multilayer barrier structure 120, and the second electrode 130 may correspond to their counterparts as described in connection with FIGS. 1-2C above. In this implementation, the memory device 810 is fabricated over the second electrode 130 of the selector 805.

The memory device 810 may be and/or include any suitable with programmable conductance, such as a memristor, MRAM, RRAM, PCM, floating gates, spintronic devices, DRAM, FeRAM, SRAM, etc. In some embodiments, the memory device 810 may include a switching oxide layer including one or more transition metal oxides, such as HfOₓ, TaOₓ, TiOₓ, NbOₓ, ZrOₓ, etc. In some embodiments, the switching oxide layer includes at least one of HfOₓ or TaOₓ, wherein x may be used to indicate the oxide being oxygen deficient compared to its full (or terminal) oxide and the value of x may be varied from the oxygen to metal atomic ratio in the stoichiometry of its full oxide, such as x≤2.0 for HfOx (where HfO₂ being the full oxide), and x≤2.5 for TaOx (where Ta₂O₅ being the full oxide).

As shown in FIG. 8B, 1S1R structure 800b may include the memory device 810 and the selector 805. In this implementation, the selector 805 is fabricated on the memory device 810. The first electrode 110, the multilayer barrier structure 120, and the second electrode 130, as described above, may be sequentially fabricated over the memory device 810. The memory device 810 may have its own device stack including a bottom electrode, switching oxides, and a top electrode, etc. The multilayer barrier structure 120 is fabricated on the first electrode 110, and the second electrode 130 is fabricated on the multilayer barrier structure 120.

While certain layers are illustrated in FIGS. 1, 2A-2C, and 8A-8B, this is merely illustrative. The selectors and the 1S1R structures described herein may include any suitable components and/or layers for implementing memory and computing applications. For example, the memory device 810 may include one or more interface layers (not shown) of one or more materials that are more chemically stable than the transition metal oxides in the switching oxide layer.

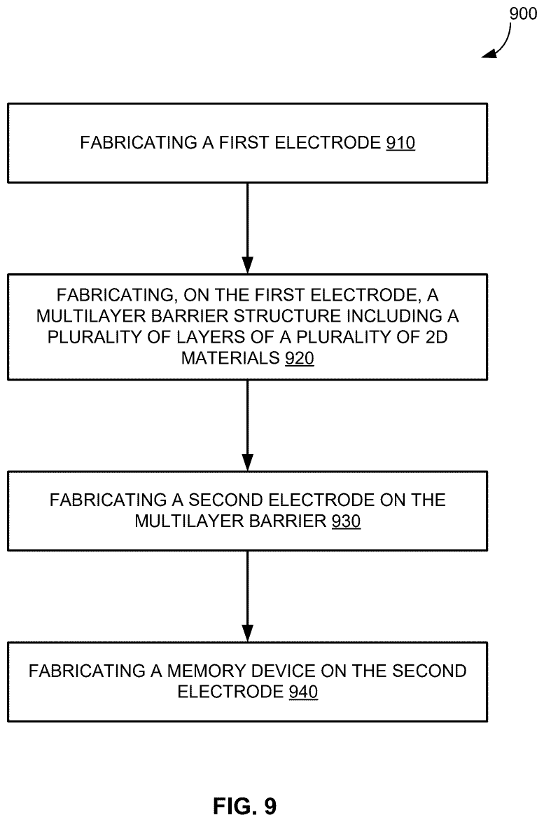

FIG. 9 is a flow diagram illustrating an example 900 of a method for fabricating a selector and/or a 1S1R structure according to some embodiments of the disclosure. The 1S1R structure may be the 1S1R structure 800a as described in connection with FIG. 8A.

At block 910, a first electrode 110 may be fabricated. The first electrode may include the first electrode 110 as described in connection with FIG. 1 above. Fabricating the first electrode may involve depositing a layer of a material of suitable electrical conductivity, such as Gr, metal, or nitride.

At block 920, a multilayer barrier structure may be fabricated on the first electrode. The multilayer barrier structure may include a plurality of layers of a plurality of 2D materials. The multilayer barrier structure may be and/or include the multilayer barrier structure 120, 120a, 120b, and/or 120c as described in connection with FIGS. 1-2C. Fabricating the multilayer barrier structure may include fabricating the layer 123n on the first electrode, fabricating the central layer 121, and fabricating the layer 125n. Fabricating the multilayer barrier structure may further include fabricating one or more layers 123i between layers 123a and 123n and one or more layers 123j between layers 125a and 125n. Each of the layers of 2D materials may be grown by various ultra-thin film deposition techniques, such as chemical vapor deposition (CVD), atomic layer deposition (ALD), physical vapor deposition (PVD), etc. In some embodiments, the multilayer barrier structure may be fabricated utilizing suitable layer transfer techniques, for example, by transferring one or more layers of 2D materials onto the first electrode and/or one or more other 2D layers of the multilayer barrier structure to fabricate the selector.

In some embodiments, one or more of the layers of 2D materials may be fabricated using remote epitaxy techniques. For example, fabricating the layers of 2D materials may involve growing epitaxial single-crystal thin films where a 2D vdW material serves as a semi-transparent interlayer. The underlying substrate remotely guides the film's crystallinity through this interlayer. The film can subsequently be peeled off from the substrate to yield free-standing layers. The 2D materials may include, for example, VO₂, GaN, WS₂, etc.

In some embodiments, one or more of the layers of 2D materials may be fabricated using MXene synthesis techniques. For example, fabricating a layer of 2D materials may start with a MAX phase that fabricates layered ternary compounds MAX with hexagonal structure, where Mₙ₊₁Xₙ layers are separated by layers of pure A (where ‘A’ commonly represents elements like Al, Ga, Si, or S). A subsequent selective etching process may then be performed to remove the A element from the MAX phase, leaving behind the M and X layers, forming the MXene phase Mₙ₊₁XₙTₓ, where T denotes termination groups on surface (F, OH, Cl or O), and x represents the number of terminations.

At block 930, a second electrode may be fabricated on the multilayer barrier structure. The second electrode may include the second electrode 130 as described in connection with FIG. 1 above. Fabricating the second electrode may involve depositing a layer of a material of suitable electrical conductivity on the memory device, such as graphene, metal, or nitride.

At block 940, a memory device may be fabricated on the second electrode of the selector device. Fabricating the memory device may involve fabricating a bottom electrode, a switching oxide layer, a top electrode, etc. The switching oxide layer may include one or more transition metal oxides, such as TaOₓ, HfOₓ, TiOₓ, NbOₓ, ZrOₓ, etc. The switching oxide layer may be deposited utilizing PVD, CVD, ALD, and/or any other suitable deposition technique. In some embodiments, the second electrode of the selector device may be used as the bottom electrode of the memory device.

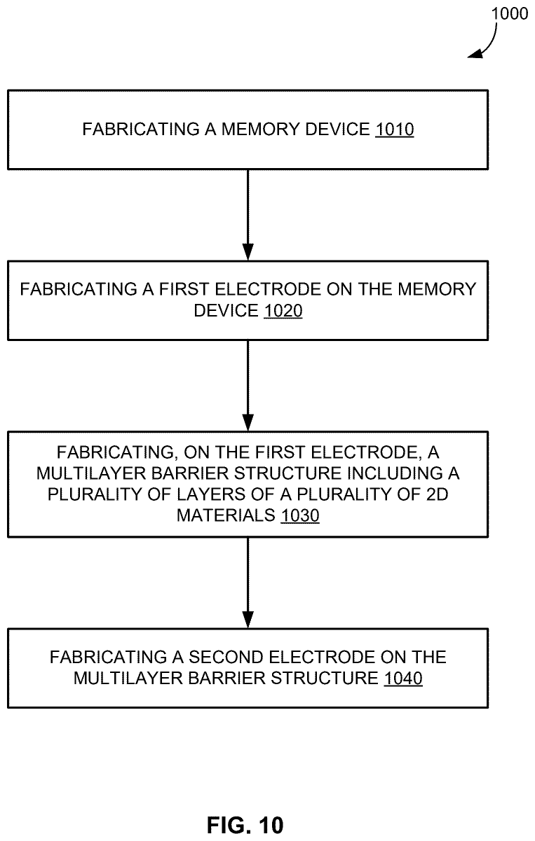

FIG. 10 is a flow diagram illustrating an example 1000 of a method for fabricating a selector and a 1S1R device according to some embodiments of the disclosure. The 1S1R structure may be the 1S1R structure 800b as described in connection with FIG. 8B.

At block 1010, a memory device may be fabricated. The memory device may be the memory device 810 as described in connection with FIG. 8B and may have its own device stack including a bottom electrode, switching oxides, a top electrode, etc. Fabricating the memory device may involve fabricating a switching oxide layer including one or more transition metal oxides, such as TaOₓ, HfOₓ, TiOₓ, NbOₓ, ZrOₓ, etc. The switching oxide layer may be deposited utilizing PVD, CVD, ALD, and/or any other suitable deposition technique.

At block 1020, a first electrode 110 may be fabricated on the memory device 810. In some embodiments, the top electrode of the memory device 810 may also be used as the first electrode 110 of the selector device.

At block 1030, a multilayer barrier structure may be fabricated on the first electrode 110. For example, one or more operations as described in connection with block 920 of FIG. 9 may be performed to fabricate the multiplayer barrier structure.

At block 1040, a second electrode may be fabricated on the multilayer barrier structure. The second electrode may include the second electrode 130 as described in connection with FIG. 1 above. Fabricating the second electrode may involve depositing a layer of a material of suitable electrical conductivity on the memory device, such as a layer of Gr, a metal, or a nitride.

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” may be used to mean within ±20% of a target dimension in some embodiments, within ±10% of a target dimension in some embodiments, within ±5% of a target dimension in some embodiments, and yet within ±2% in some embodiments. The terms “approximately” and “about” may include the target dimension.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. A selector, comprising:
a multilayer barrier structure fabricated between a first electrode and a second electrode, wherein the multilayer barrier structure comprises:
a first layer comprising a first two-dimensional (2D) material, wherein the first 2D material comprises gallium sulfide (GaS);
a second layer comprising a second 2D material; and
a third layer comprising a third 2D material, wherein a first electron affinity of the first layer comprising the first 2D material is lower than a second electron affinity of the second layer comprising the second 2D material and a third electron affinity of the third layer comprising the third 2D material, wherein the first layer comprising the first 2D material is fabricated between the second layer comprising the second 2D material and the third layer comprising the third 2D material.

2. The selector of claim 1, wherein the first electrode comprises graphene, and wherein the second electrode comprises graphene, a metal, or a nitride.

3. The selector of claim 1, wherein the second 2D material comprises WS₂, and wherein the third 2D material comprises WS₂.

4. The selector of claim 1, wherein the second 2D material comprises MoS₂, and wherein the third 2D material comprises MoS₂.

5. The selector of claim 1, wherein the second 2D material comprises MoTe₂, and wherein the third 2D material comprises MoTe₂.

6. The selector of claim 1, wherein the multilayer barrier structure further comprises a fourth layer of a fourth 2D material, wherein the second electron affinity of the second 2D material is lower than a fourth electron affinity of the fourth 2D material, and wherein the fourth layer of the fourth 2D material is fabricated between the second layer comprising the second 2D material and the first electrode.

7. The selector of claim 6, wherein the multilayer barrier structure further comprises a fifth layer of a fifth 2D material, wherein the third electron affinity of the third layer of the third 2D material is lower than a fifth electron affinity of the fifth layer of the fifth 2D material, and wherein the fifth layer of the fifth 2D material is fabricated between the third layer comprising the third 2D material and the second electrode.

8. The selector of claim 7, wherein the second 2D material comprises WSe₂, wherein the third 2D material comprises WSe₂, and wherein the fourth 2D material and the fifth 2D material comprise at least one of MoTe₂, WS₂, or MoS₂.

9. The selector of claim 7, wherein the second 2D material comprises MoTe₂, wherein the third 2D material comprises MoTe₂, and wherein the fourth 2D material and the fifth 2D material comprise at least one of WS₂ or MoS₂.

10. The selector of claim 7, wherein the second 2D material comprises WS₂, wherein the third 2D material comprises WS₂, and wherein the fourth 2D material and the fifth 2D material comprise MoS₂.

11. The selector of claim 1, wherein the multilayer barrier structure comprises 2n+1 layers of 2D materials, wherein n is a positive integer.

12. The selector of claim 1, wherein the multilayer barrier structure forms a staircase tunnel barrier approximating a triangular tunnel barrier.

13. An apparatus, comprising:
a selector comprising:
a multilayer barrier structure fabricated between a first electrode and a second electrode, wherein the multilayer barrier structure comprises:
a first layer comprising a first two-dimensional (2D) material, wherein the first 2D material comprises gallium sulfide (GaS);
a second layer comprising a second 2D material; and
a third layer comprising a third 2D material, wherein a first electron affinity of the first layer comprising the first 2D material is lower than a second electron affinity of the second layer comprising the second 2D material and a third electron affinity of the third layer comprising the third 2D material; and
a memory device serially connected to the selector.

14. The apparatus of claim 13, wherein the memory device comprises at least one of a memristor, resistive random-access memory (RRAM), phase-change memory (PCM), magneto-resistive random-access memory (MRAM), floating gates, spintronic devices, dynamic random-access memory (DRAM), ferroelectric random-access memory (FeRAM), or static random-access memory (SRAM).

15. The apparatus of claim 13, wherein the second 2D material comprises at least one of MoS₂, WS₂, MoTe₂, or WSe₂, and wherein the third 2D material comprises at least one of MoS₂, WS₂, MoTe_{2,} or WSe₂.

16. The apparatus of claim 13, wherein the multilayer barrier structure further comprises a fourth layer of a fourth 2D material, wherein the second electron affinity of the second 2D material is lower than a fourth electron affinity of the fourth 2D material, wherein the fourth layer of the fourth 2D material is fabricated between the second layer comprising the second 2D material and the first electrode, and wherein the multilayer barrier structure further comprises a fifth layer of a fifth 2D material, wherein the third electron affinity of the third layer of the third 2D material is lower than a fifth electron affinity of the fifth layer of the fifth 2D material, and wherein the fifth layer of the fifth 2D material is fabricated between the third layer comprising the third 2D material and the second electrode.

17. The apparatus of claim 16, wherein the second 2D material comprises WSe₂, wherein the third 2D material comprises WSe₂, and wherein the fourth 2D material and the fifth 2D material comprise at least one of MoTe₂, WS₂, or MoS₂.

18. The apparatus of claim 16, wherein the second 2D material comprises MoTe₂, wherein the third 2D material comprises MoTe₂, and wherein the fourth 2D material and the fifth 2D material comprise at least one of WS₂ or MoS₂.

19. The apparatus of claim 16, wherein the second 2D material comprises WS₂, wherein the third 2D material comprises WS₂, and wherein the fourth 2D material and the fifth 2D material comprise MoS₂.

20. The apparatus of claim 13, wherein the selector has a staircase tunnel barrier approximating a triangular tunnel barrier.
